(19) United States
(12) Patent Application Publication
(10) Pub. No.: US 2013/0328564 A1
(43) Pub. Date: Dec. 12, 2013

(54) NMR RF PROBE COIL EXHIBITING DOUBLE RESONANCE

(71) Applicants: University of Florida Research Foundation, Incorporated, Gainesville, FL (US); The Florida State University Research Foundation, Inc., Tallahassee, FL (US)

(72) Inventors: William W. Brey, Tallahassee, FL (US); Arthur Edison, Gainesville, FL (US); Vijaykumar Ramaswamy, Gainesville, FL (US); Jerris Hooker, Tallahassee, FL (US)

(21) Appl. No.: 13/916,231

(22) Filed: Jun. 12, 2013

Related U.S. Application Data
(60) Provisional application No. 61/658,706, filed on Jun. 12, 2012.

(51) Int. Cl. G01R 33/385

(52) U.S. Cl. CPC G01R 33/385
USPC 324/320

(57) ABSTRACT

The present invention describes NMR probe coils that are designed to operate at two different frequencies, producing a strong and homogenous magnetic field at both the frequencies. This single coil, placed close to the sample, provides a method to optimize the NMR detection sensitivity of two different channels. In addition, the present invention describes a coil that generates a magnetic field that is parallel to the substrate of the coil as opposed to perpendicular as seen in the prior art. The present invention isolates coils from each other even when placed in close proximity to each other. A method to reduce the presence of electric field within the sample region is also considered. Further, the invention describes a method to adjust the radio-frequency tuning and coupling of the NMR probe coils.

### FEDERALLY SPONSORED RESEARCH OR DEVELOPMENT

This invention was made with Government support under Grant No. 1R01EB009772-01 awarded by National Institute of Health thru a subcontract from the University of Florida, Primary Investigator: Arthur Edison. The government has certain rights in the invention.

### BACKGROUND OF THE INVENTION

1. Field of the Invention

This invention relates to nuclear magnetic resonance (NMR). More specifically, it relates to Radio Frequency (RF) transmit-receive coils.

2. Brief Description of the Related Art

NMR is a very powerful yet inherently insensitive technique for analyzing molecular structure and dynamics. To gain maximum sensitivity, NMR spectrometers are designed to operate at high magnetic field strengths, and consequently the spectrum of NMR signals is in the radio frequency range. The transmit/receive coils are the probe coils that stimulate the nuclei and detect the NMR response from the sample. The sensitivity of the probe coils is primarily dependent on two factors—coil Quality factor (Q-factor) and filling factor. The Q-factor can be improved by constructing the coil out of low loss materials, such as high temperature superconducting (HTS) materials. The filling factor can be improved by placing the coil very close to the sample. In multi-channel NMR probes, therefore, the sensitivity of each channel decreases as the distance between coils and the sample increases. It is possible to optimize the sensitivity of only one channel at a time, namely, the coil placed closest to the sample. Furthermore, the placement of coils, known in the prior art, in very close proximity to each other causes undesirable interaction between them.

An NMR probe coil provides the RF magnetic field to the sample, thereby stimulating the nuclear spins and detects the response of the nuclear spins.

When RF current flows through the windings of the NMR probe coil, an RF magnetic field is produced perpendicular to the direction of the current. An RF transmit current forced into the coil produces an RF magnetic field in the sample region, which excites the nuclear spins. Conversely, the RF magnetic field caused by the precession motion of the nuclear spins induces an RF current in the coil windings. In the transmit mode, the strength of the magnetic field decays away with an increase in the distance from the coil, as determined by the Biot-Savart law. By reciprocity, in the receive mode, the strength of the induced current in the coil decays as the distance between sample and coil increases. Under these conditions, it is desirable for optimal sensitivity, to design the NMR probe coils to be placed as close as possible to the sample.

The other important factor affecting the performance of the RF probe coils is the coil Q-factor. The Q-factor can be improved by lowering the loss in the material of the coil. This may be achieved by either lowering the temperature of the normal metal coils, or by using superconducting material. NMR probe coils are commonly fashioned out of HTS materials. This is achieved by patterning the HTS on planar dielectric substrates. Such planar coils offer severe constraints to placing the coils very close to the sample. For NMR excitation and detection of multiple channels, the RF probes known in the prior art utilize one pair of coils for each channel. In this embodiment, the pair of coils that is placed closest to the sample performs at its optimum to achieve excellent sensitivity. Each additional channel requires a pair of coils nested outside all the other channels. As channels are added, each additional pair of coils must be placed farther away from the sample, providing lower and lower sensitivity. A NMR field frequency lock channel typically used for analytical NMR requires its own coil pair in addition to the others. A typical “triple resonance” NMR probe of the type commonly used for biomolecular structure experiments requires a total of four nested pairs of coils, and of these only the inner pair is optimized for sensitivity.

Self-resonant coils made from thin-film oxide superconductors such as YBCO are used as NMR detection coils because of their extremely high quality factors. Electrical energy is coupled into and out of these coils by means of inductive coupling to a wire loop at the end of a coaxial transmission line. Mechanical adjustment of the position of the wire loop is used to adjust the coupling to match the coil impedance to the characteristic impedance of the transmission line. A related adjustment of radio frequency properties is known as tuning Tuning refers to a shift in resonant frequency of the NMR coil. In HTS, this shift is accomplished by moving a shorted wire loop so that it intercepts a variable amount of flux from the NMR coil.

The moving loop approach for tuning and matching has some important disadvantages. Most importantly, moving a loop and coaxial cable close to the NMR sample will tend to change the uniformity of the polarizing magnetic field. In NMR, chemical resolution is typically limited by the uniformity of the polarizing field. Great effort is made to adjust this uniformity in a process called “shimming.” Even if the loop is made from state of the art susceptibility-compensated wire, the effect is noticable. It is therefore not possible to adjust the RF coupling (known as matching) or the tuning without affecting the resolution, requiring a time consuming step of re-shimming the magnet.

A second drawback of moving loops is basic to the use of moving parts in almost any device. Moving parts tend to be less reliable than other approaches.

Additionally, the number of nested pairs required for a triple resonance NMR probe places a limit on the sample diameter that can practically be accommodated. To achieve reasonable sensitivity and field homogeneity, each coil pair must be at least as wide as the gap between the coils. Within a “standard bore” NMR magnet, shim and pulsed field gradient coil, there is not enough room to nest more than about 3 channels around a standard 5 mm diameter sample tube. There is very little space available in NMR probes, and the need for independent loops for the two functions makes the design, construction, adjustment and repair of HTS NMR probes significantly more difficult and time consuming. There is not space to accommodate the coils required for a triple resonance probe which requires four channels and four nested pairs.

However, in view of the art considered as a whole at the time the present invention was made, it was not obvious to those of ordinary skill in the field of this invention how the shortcomings of the prior art could be overcome.

### BRIEF SUMMARY OF THE INVENTION

The long-standing but heretofore unfulfilled need for a single coil NMR probe that can operate at two different frequencies, producing a strong and homogenous magnetic field at both frequencies that reduces electric fields within the sample region is now met by a new, useful, and nonobvious invention.

The novel structure includes two sets of RF coils. Each RF coil consists of conductive material patterned on a dielectric substrate. The two sets of coils form a sample region between them for positioning the NMR sample.

In one possible arrangement, each coil set at one of the two resonance frequencies are exclusive of the current-carrying elements at the other frequency. The coils can be placed on the dielectric substrate in three different configurations. One configuration is where the coils are placed on opposite sides of the dielectric substrate. Another has the coils patterned on two separate dielectric substrates which are then fastened together. The final orientation has the coils placed on the same side of the dielectric substrate with one coil placed within another.

In an alternative arrangement, the current-carrying elements are not exclusive of each other at the two resonance frequencies. Capacitive coupling can be achieved between the two coils across the substrate at one of the two frequencies.

In another alternative arrangement, the NMR probe can have the current-carrying elements of each coil set at two frequencies that are the same. The two resonances are then produced due to differences in the current density distribution at the two frequencies.

The long-standing but heretofore unfulfilled need for a method that facilitates the use of two RF coils in very close proximity with very little interaction is now met by a new, useful, and nonobvious invention.

The method involves positioning the two coils so that the net magnetic flux generated by one coil and flowing through another coil is zero. As a result of this placement the magnetic fields produced by each coil at its operating frequency is orthogonal to the magnetic field produced by the other coil.

An NMR probe coil consisting of conductive elements patterned on a dielectric substrate forming a resonant device. The current in the coil at the resonance frequency flows through a central conductor, and flows back in the reverse direction through distal conductors. This creates a magnetic field within a sample region that is parallel to the dielectric substrate.

Making the central conductor wider near the middle and tapering near the end along the long axis of the coil will help improve the homogeneity of the magnetic field of the NMR probe coil.

A single fixed loop is used to couple electrical energy into and out of the HTS NMR coils. The loop is terminated by a network of trimmer capacitors which will be adjusted to vary both the coupling and the resonant frequency of the NMR coil. This single fixed loop replaces two loops in the prior art.

In order to allow for adjustments to tuning and matching, the single loop must be in an over coupled condition to the NMR coil. This means that the impedance at the loop terminals looking toward the coil at the coil resonance frequency will be less than the characteristic impedance of the transmission line. The amount of coupling needed will be set during the design process based on the inductance and quality factor of the NMR coil, the tuning range needed, and the anticipated loss in the NMR sample itself.

It is important to minimize electrical loss in the fixed coupling loop. Such loss is a function of two processes. First is loss due to the desired currents induced along the length of the coupling loop which is needed for coupling and tuning These loops increase proportionally with the series resistance of the wire. In the typical limit for RF circuits, where the wire thickness is much greater than the skin depth, the series resistance varies inversely with the wire radius. This transport loss is then inversely proportional to wire radius, so it is desirable to use a wire of large radius. However, magnetic flux perpendicular to the finite surface area of the wire will induce so-called eddy currents in the wire which also contribute loss. A wire of larger radius will be subject to greater eddy current loss. So there is an optimal wire radius which can be determined for each case. The location and shape of the fixed coupling loop can also be adjusted to maximize coupling while minimizing eddy current loss. Because the loop is fixed, the wire will remain in the configuration of minimum loss at all times.

### BRIEF DESCRIPTION OF THE DRAWINGS

For a fuller understanding of the invention, reference should be made to the following detailed description, taken in connection with the accompanying drawings, in which:

FIG. 1 is a an illustration of Prior Art;

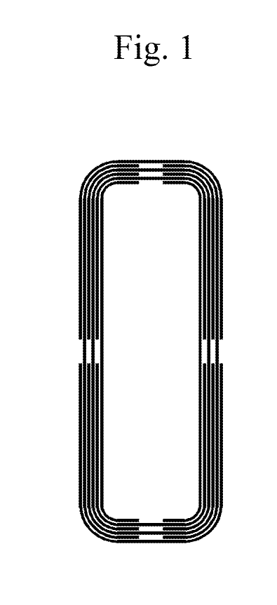

FIG. 2 is a preferred embodiment of the invention, a ¹³C—¹H coil;

FIG. 3 is another preferred embodiment of the invention, a ¹⁵N—²H coil;

FIG. 4 is another preferred embodiment of the invention.

### DETAILED DESCRIPTION OF THE PREFERRED EMBODIMENT

The described embodiments provide doubly resonant coils that generate strong and homogenous magnetic field at two resonance frequencies. The current distribution in these two resonance modes is such that the magnetic fields within the sample region are orthogonal to each other. In a preferred embodiment, a set of two coils whose magnetic fields are orthogonal to each other within the sample region is used to excite and detect the two frequencies, thereby allowing for independent design optimization with almost negligible interaction between the two coils. In another embodiment, quadrature detection of NMR signal at one frequency may be achieved by designing two coils to operate at the same frequency.

The NMR probe coils, known in the prior art and operating at their fundamental resonance frequency, generate a magnetic field perpendicular to the substrate of the coil. The pair of coils straddling the sample on either side forms a Helmholtz pair, and the magnetic field homogeneity is determined by the Helmholtz condition. The present invention describes NMR coil designs which generate a magnetic field that is parallel to the substrate of the coil. The pair of coils on either side of the sample carries currents in counter directions, in order that the magnetic fields from both the coils are additive. A method to optimize the homogeneity of the magnetic field is by adjusting the width and shape of the central conducting strip.

The presence of electric field within the sample region is a source of loss in NMR experiments. In the design of NMR probes, it is desirable that the coils have the lowest possible electric field in the sample region, so as to achieve high sensitivity. Various means of reducing the electric field is known in the art. In a preferred embodiment of the invention, the coil used to generate the magnetic field at one of the frequencies is used as a mechanism to shield the electric field at the other frequency. In a further preferred embodiment, dedicated electric field shields are used to reduce the electric field penetrating into the sample region.

It will be appreciated by those skilled in the art that a number of variations are possible within the spirit and scope of the invention. The scope of the invention should not be limited by the specific examples given above, but by the appended claims.

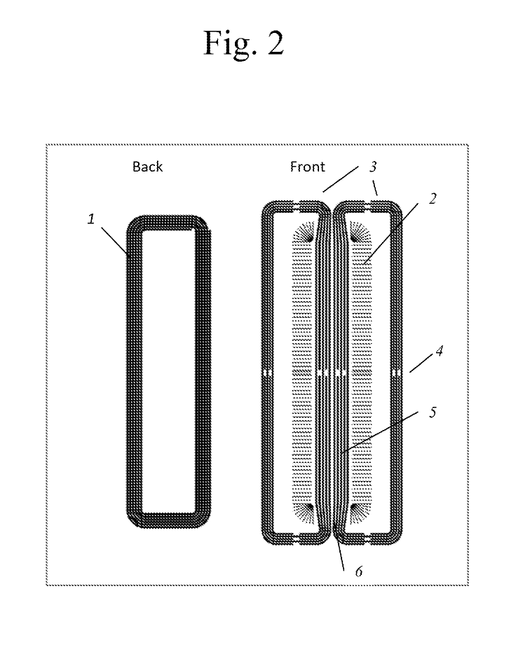

FIG. 2 illustrates a preferred embodiment of the invention, a ¹³C—¹H coil. This example is appropriate to use as the inner coil pair in an NMR probe designed for detection of both ¹³C and ¹H isotopes. In this embodiment, a dielectric substrate (not shown) separates two superconductive films patterned into self-resonant coil structures. Two such films are disposed around a cylindrical sample as in prior art to produce a uniform RF magnetic field across the sample. The long axis of the coil would be oriented along the field axis of the solenoidal NMR magnet. The side away from the sample (labeled “back) is patterned into a simple spiral (2). The spiral produces a field which is predominately perpendicular to the plane of the dielectric substrate. The spiral is well suited to achieving low resonance frequencies associated with ¹³C, ¹⁵N and other nuclei excluding ¹H and ¹⁹F. However, the electric field of the spiral fringes away from the dielectric substrate and into the sample under analysis. The conductivity and dielectric loss of the sample are often enough to reduce the Q of the coil and contribute to the noise of the NMR measurement.

To improve sensitivity on the ¹³C channel, the preferred embodiment incorporates a Faraday shield (2) on the side of the substrate facing the sample as described in U.S. Pat. No. 7,446,534. The shield consists of thin, closely spaced wires that do not greatly affect the magnetic field produced by (1). The high frequency (typically ¹H) resonator is patterned on the “front” side of each dielectric substrate, facing the sample. The building block for the ¹H coil is the “racetrack” resonator as described in U.S. Pat. No. 5,565,778 which is incorporated by reference. Two racetrack resonators (3) are patterned adjacent to each other. The resulting structure resembles the figure-8 coil described in U.S. Pat. No. 4,973,908 (also incorporated by reference), and produces an RF magnetic field which is substantially parallel to the dielectric substrate and orthogonal to the field produced by the spiral on the back of the substrate. The racetrack resonator can be readily tuned to the higher frequency of the ¹H isotope. When broken with several gaps (4), in this case with four gaps, the racetrack has a low fringing electric field and is very suitable for use close to a lossy biomolecular sample. Both the spiral (2) and the racetrack (3) should be patterned into thin parallel wires as taught in the '778 patent to reduce distortions of the polarizing magnetic field. Therefore, in areas where (2) and (4) overlap, where it is not possible to continue the Faraday shield (2), the racetrack itself serves as a Faraday shield for the spiral and does not greatly affect the magnetic field of the spiral. In NMR spectroscopy it is important to produce a uniform RF magnetic field over the sample. The field of the figure-8 coil will not be as uniform, in general, as that of the pair of rectangular resonators. However, the uniformity can be greatly improved by widening the central region of the center portion (5) of the figure-8 coil. It is advantageous for RF homogeneity to taper the center portion at the ends as shown in FIG. 2.

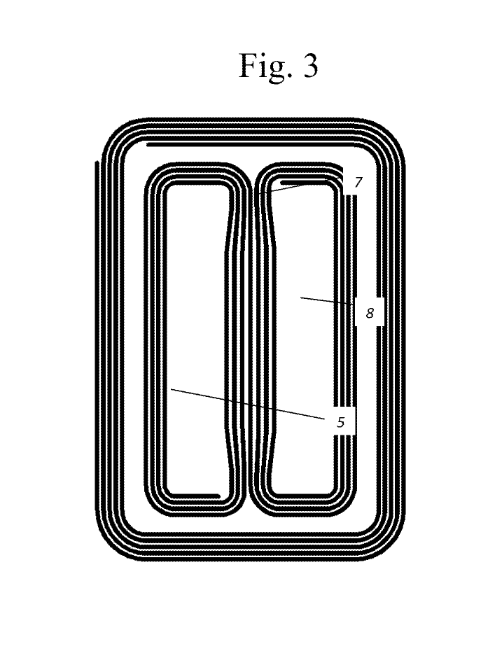

FIG. 3 illustrates another preferred embodiment of the invention, a ¹⁵N-²H coil. This example is appropriate to use as the outer coil pair in an NMR probe designed for decoupling on the ¹⁵N channel and for engaging a ²H field frequency lock. In this embodiment, both the self-resonant coil structures are patterned on the same side of the dielectric substrate, thereby eliminating the slightly trickier two-sided patterning of the HTS coils. The long axis of the coil would be oriented along the field axis of the solenoidal NMR magnet. The coil consists of a figure-8 (7) coil tuned to the ²H frequency and a simple spiral (8) tuned to the ¹⁵N frequency. The magnetic field in the sample region at the spiral resonance frequency is substantially perpendicular to the dielectric substrate, whereas the magnetic field in the sample region at the figure-8 coil resonance frequency is substantially parallel to the dielectric substrate. The central region of the center portion (5) of the figure-8 coil is widened as before to provide better RF homogeneity.

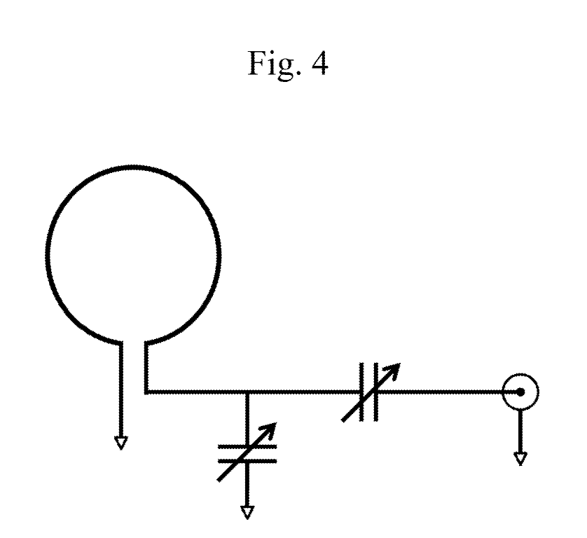

FIG. 4 depicts a single fixed loop in accordance with a preferred embodiment of the present invention. The single fixed loop is used to couple electrical energy into and out of the HTS NMR coils. The loop is terminated by a network of trimmer capacitors which will be adjusted to vary both the coupling and the resonant frequency of the NMR coil. This single fixed loop replaces two loops in the prior art.

In order to allow for adjustments to tuning and matching, the single loop must be in an over coupled condition to the NMR coil. This means that the impedance at the loop terminals looking toward the coil at the coil resonance frequency will be less than the characteristic impedance of the transmission line. The amount of coupling needed will be set during the design process based on the inductance and quality factor of the NMR coil, the tuning range needed, and the anticipated loss in the NMR sample itself.

It is important to minimize electrical loss in the fixed coupling loop. Such loss is a function of two processes. First is loss due to the desired currents induced along the length of the coupling loop which is needed for coupling and tuning These loops increase proportionally with the series resistance of the wire. In the typical limit for RF circuits, where the wire thickness is much greater than the skin depth, the series resistance varies inversely with the wire radius. This transport loss is then inversely proportional to wire radius, so it is desirable to use a wire of large radius. However, magnetic flux perpendicular to the finite surface area of the wire will induce so-called eddy currents in the wire which also contribute loss. A wire of larger radius will be subject to greater eddy current loss. So there is an optimal wire radius which can be determined for each case. The location and shape of the fixed coupling loop can also be adjusted to maximize coupling while minimizing eddy current loss. Because the loop is fixed, the wire will remain in the configuration of minimum loss at all times.

The advantages set forth above, and those made apparent from the foregoing description, are efficiently attained. Since certain changes may be made in the above construction without departing from the scope of the invention, it is intended that all matters contained in the foregoing description or shown in the accompanying drawings shall be interpreted as illustrative and not in a limiting sense.

### GLOSSARY OF CLAIM TERMS

Capacitance: The ability of a body to store an electrical charge
Capacitive coupling: Transfer of energy within an electric network by means of capacitance between circuit nodes.
Central conductor: Object or substance which allows heat, electricity, light or sound to pass along it or through it. Central means it is in or towards the center of the body.
Current-carrying elements: An element capable of carrying a current.
Dieletric substrate: Electrical insulators such as silicon, ceramic quartz, etc. It is selected with dielectric strength, dielectric constant and loss tailored for specific circuit application in order to serve as a base for another material. Generally, it is a nonconductor of electricity with electrical conductivity of less than a millionth (10⁻⁶) of a siemens.
Distal conductors: Object or substance which allows heat, electricity, light or sound to pass along it or through it. Distal means it is oriented away from the center of the body or from point of attachment.
NMR Probe: The probe is part of an NMR spectrometer responsible for a significant portion of the work. The probe is placed in the center of the magnetic field, and the sample is inserted into the center of the probe. The probe contains radiofrequency coils (RF) tuned at specific frequencies for specific nuclei.
Nuclear Magnetic Resonance (NMR): Is a physical phenomenon in which magnetic nuclei in a magnetic field absorb and re-emit electromagnetic radiation. The energy that is re-emitted is at a specific resonance frequency which depends on the strength of the magnetic field and magnetic properties of the isotope of the atoms.
Orthogonal: Comes from the Greek word “orthos” meaning straight. Involves the idea of perpendicular, non-overlapping, varying independently or uncorrelated.
Parallel: Of, relating to, or designating two or more straight coplanar lines that do not intersect.
Perpendicular: Intersecting or forming a 90 degree (right) angle
Resonance: The tendency of a system to oscillate at varying amplitude at some frequency. The level of amplitude is greater at some frequencies than others.
RF coils: Coils contained within the probe tuned at specific frequencies for specific nuclei.

What is claimed is:

1. An apparatus for an NMR probe comprising:
two sets of RF coils forming a sample region between them for positioning an NMR sample wherein each set of RF coils consists of conductive material patterned on a dielectric substrate; and
is resonant at two distinct radio frequencies, wherein the magnetic fields generated at the two resonance frequencies are orthogonal to each other; and
said magnetic fields employed to excite and detect NMR signals at said resonance frequencies.

2. The NMR probe of claim 1, wherein the current-carrying elements of each coil set at one of the two resonance frequencies are exclusive of the current-carrying elements at the other frequency.

3. The NMR probe in claim 2, wherein one coil is placed on one side of the dielectric substrate and the other coil on the opposite side of the dielectric substrate.

4. The NMR probe in claim 2, wherein the two coils are patterned on two dielectric substrates, which are subsequently fastened together.

5. The NMR probe in claim 2, wherein the two coils are placed on the same side of the dielectric substrate, and one coil is placed within the other coil.

6. The NMR probe of claim 1, wherein there is capacitive coupling between the two coils across the substrate at one of the two frequencies, and current-carrying elements of the coil set.

7. The NMR probe of claim 1, wherein the current-carrying elements of each coil set at the two frequencies are the same, whereby the two resonances are produced due to differences in the current density distribution at the two frequencies.

8. An NMR probe coil comprising conductive elements patterned on a dielectric substrate forming a resonant device, wherein the current in the coil at the resonance frequency flows through a central conductor, and flows back in the reverse direction through distal conductors, and the corresponding magnetic field within the sample region is substantially parallel to the dielectric substrate.

9. A method to improve the homogeneity of the magnetic field of the NMR probe coil of claim 8, achieved by making the central conductor wider near the middle and tapering near the ends along the long axis of the coil.

10. An apparatus for an NMR probe comprising a fixed inductive coupling loop which is used to transfer energy into and out of the RF coils, wherein the loop is terminated by a network of adjustable capacitors which can be adjusted to achieve tuning and coupling of the RF coils.

11. The NMR probe in claim 11, where the said coupling loop is fabricated from normal metallic conductors.

12. The NMR probe in claim 11, where the said coupling loop is fabricated from high temperature superconductors.
